(19) United States
(12) Patent Application Publication
(10) Pub. No.: US 2020/0006629 A1
(43) Pub. Date: Jan. 2, 2020

(54) SYSTEMS AND METHODS FOR MITIGATING ENCROACHMENT IN MAGNETORESISTIVE DEVICES

(71) Applicant: Everspin Technologies, Inc., Chandler, AZ (US)

(72) Inventor: Han-Jong CHIA, Chandler, AZ (US)

(73) Assignee: Everspin Technologies, Inc., Chandler, AZ (US)

(21) Appl. No.: 16/023,494

(22) Filed: Jun. 29, 2018

(51) Int. Cl. H01L 43/02; H01F 10/32; H01F 41/32

(52) U.S. Cl. CPC H01L 43/02; H01F 10/3254; H01L 43/10; H01F 41/32; H01F 10/3286

(57) ABSTRACT

As magnetoresistive stack structures are made in increasing smaller form factors, encroachment in layers of magnetoresistive stack structures may affect the energy required to write magnetic states to the stack structures. Encroachment may be observed as, e.g., an increase in switching voltage (V_{C}) and an increase in switching voltage distribution (V_{Cσ}) as magnetoresistive stack size decreases, caused by differences between a peripheral portion and an inner portion of a region in a magnetoresistive stack. Embodiments of the present disclosure relate to systems and methods for controlling, reducing, or otherwise mitigating the effects of encroachment in magnetoresistive stacks.

### TECHNICAL FIELD

The present disclosure relates to, among other things, magnetoresistive stacks, devices including magnetoresistive stacks, and systems and methods for controlling, reducing, or otherwise mitigating encroachment, such as magnetic encroachment or electrical encroachment resulting from one or more fabrication steps and/or process during manufacture of the magnetoresistive stacks.

### INTRODUCTION

There are many inventions described and illustrated herein, as well as many aspects and embodiments of those inventions. In one aspect, the present disclosure relates to magnetoresistive structures (for example, part of a magnetoresistive memory device, magnetoresistive sensor/transducer device, etc.) and methods of manufacturing the described magnetoresistive structures. For example, the disclosed structures may be related to magnetoresistive random access memory (MRAM) devices, magnetoresistive sensor/transducer devices, etc. To describe aspects of the disclosed devices and methods, exemplary magnetoresistive stack configurations are described. However, these are only exemplary. The disclosed devices can have many other stack configurations, and the disclosed methods can be applied to manufacture magnetoresistive devices having various suitable magnetoresistive stacks.

Briefly, a magnetoresistive memory stack used in a memory device (e.g., a MRAM device) includes at least one non-magnetic layer (for example, at least one dielectric layer or a non-magnetic yet electrically conductive layer) disposed between a “fixed” magnetic region and a “free” magnetic region, each including one or more layers of ferromagnetic materials. Information may be stored in the magnetoresistive memory stack by switching, programming, and/or controlling the direction of magnetization vectors in the magnetic layer(s) of the “free” magnetic region of the stack. The direction of the magnetization vectors of the “free” magnetic region may be switched and/or programmed (for example, through spin transfer torque (STT) or spin orbit transfer (SOT)) by application of a write signal (e.g., one or more current pulses) through the magnetoresistive stack. In contrast, the magnetization vectors in the magnetic layers of a “fixed” magnetic region are magnetically fixed in a predetermined direction. When the magnetization vectors of the “free” magnetic region adjacent to the non-magnetic layer are in the same direction as the magnetization vectors of the “fixed” magnetic region adjacent to the non-magnetic layer, the magnetoresistive stack has a first magnetic state. Conversely, when the magnetization vectors of the “free” magnetic region adjacent to the non-magnetic layer are opposite the direction of the magnetization vectors of the “fixed” magnetic region adjacent to the non-magnetic layer, the magnetoresistive stack has a second magnetic state different from the first magnetic state. The magnetic state of the magnetoresistive memory stack is determined or read based on the resistance of the magnetoresistive stack in response to a read current. The magnetoresistive memory stacks, combinations of such stacks, and devices including such stacks disclosed herein may have some or all of these characteristics. The present disclosure also relates to systems and methods for improving magnetoresistive stacks, and such systems and methods may apply to magnetoresistive stacks disclosed herein, combinations thereof, and devices including such magnetoresistive stacks, as well as to any other now-known or future-developed magnetoresistive stacks to which one of ordinary skill in the art would find the disclosed systems and methods applicable.

### BRIEF DESCRIPTION OF THE DRAWINGS

Embodiments of the present disclosure may be implemented in connection with aspects illustrated in the attached drawings. These drawings show different aspects of the present inventions and, where appropriate, reference numerals illustrating like structures, components, materials and/or elements in different figures are labeled similarly. It is understood that various combinations of the structures, components, and/or elements, other than those specifically shown, are contemplated and are within the scope of the present disclosure.

For simplicity and clarity of illustration, the figures depict the general structure and/or manner of construction of the various embodiments described herein. For ease of illustration, the figures depict the different regions along the thickness of the illustrated stacks as a layer having well-defined boundaries with straight edges (e.g., depicted using lines). However, one skilled in the art would understand that, in reality, at an interface between adjacent regions or layers, the materials of these regions may alloy together, or migrate into one or the other material, and make their boundaries and corners ill-defined or diffuse. That is, although multiple layers with distinct interfaces are illustrated in the figures, in some cases, over time and/or exposure to high temperatures, materials of some of the layers may migrate into or interact with materials of other layers to present a more diffuse interface between these layers. Further, although the figures illustrate each region or layer as having a relatively uniform thickness across its width, one of ordinary skill in the art would recognize that, in reality, the different regions may have a non-uniform thickness (e.g., the thickness of a layer may vary along the width of the layer), and/or the thickness of one region or layer may differ relative to the thickness of another (e.g., adjacent) region or layer. Moreover, while certain regions/layers and features are illustrated with straight 90-degree edges, in reality, such regions/layers may be more “rounded” and/or gradually sloping.

There are many embodiments described and illustrated herein. The present disclosure is neither limited to any single aspect nor embodiment thereof, nor to any combinations and/or permutations of such aspects and/or embodiments. It should be noted that, even if it is not specifically mentioned, aspects described with reference to one embodiment may also be applicable to, and may be used with, other embodiments. For the sake of brevity, certain permutations and combinations are not discussed and/or illustrated separately herein. Notably, an embodiment or implementation described herein as “exemplary” is not to be construed as preferred or advantageous, for example, over other embodiments or implementations; rather, it is intended to reflect or indicate that the embodiment(s) is/are “example” embodiment(s). Further, even though the figures and this written disclosure appear to describe the disclosed structures in a particular order of construction (e.g., from bottom to top), it is understood that the depicted structures stacks may have a different order (e.g., the opposite order (i.e., from top to bottom)). For example, a “fixed” magnetic region may be formed on or above a “free” magnetic region, which in turn may be formed on or above an insertion layer of the present disclosure.

In the figures and description, details of well-known features (e.g., interconnects, etc.) and manufacturing techniques (e.g., deposition techniques, etching techniques, etc.) may be omitted for the sake of brevity (and to avoid obscuring other features and details), since these features/techniques are well known to those of ordinary skill in the art. Elements in the figures are not necessarily drawn to scale. The dimensions of some features may be exaggerated relative to other features to improve understanding of the exemplary embodiments. Cross-sectional views are simplifications provided to help illustrate the relative positioning of various regions/layers and to describe various processing steps. One skilled in the art would appreciate that the cross-sectional views are not drawn to scale and should not be viewed as representing proportional relationships between different regions/layers.

FIGS. 1A and 1B are schematic diagrams of a cross-sectional view (FIG. 1A) and a top-down plan view (FIG. 1B) of an exemplary magnetoresistive stack, according to aspects of the present disclosure.

FIG. 2 depicts a plot of switching voltage V_{C} as a function of electrical diameter (eCD) of magnetoresistive stacks, according to aspects of the present disclosure.

FIG. 3 depicts a plot of switching voltage distribution V_{Cσ} as a function of electrical diameter (eCD) of magnetoresistive stacks, according to aspects of the present disclosure.

FIG. 4 is a schematic diagram of an exemplary magnetoresistive memory element electrically connected to an access transistor in a magnetoresistive memory cell configuration.

FIGS. 5A-5D are cross-sectional schematic illustrations of exemplary magnetoresistive bits, according to aspects of the present disclosure.

FIGS. 6A and 6B are schematic block diagrams of integrated circuits including a discrete memory device and an embedded memory device, each including an MRAM (which, in one embodiment is representative of one or more arrays of MRAM having a plurality of magnetoresistive memory stacks according to aspects of certain embodiments of the present disclosure).

Again, there are many embodiments described and illustrated herein. The present disclosure is neither limited to any single aspect nor embodiment thereof, nor to any combinations and/or permutations of such aspects and/or embodiments. Each of the aspects of the present disclosure, and/or embodiments thereof, may be employed alone or in combination with one or more of the other aspects of the present disclosure and/or embodiments thereof. For the sake of brevity, many of those combinations and permutations are not discussed separately herein.

### DETAILED DESCRIPTION

Embodiments of the present disclosure relate to systems and methods for improving magnetoresistive stacks and/or layers within magnetoresistive stacks, or improving the electrical characteristics of the magnetoresistive stacks or layers/regions therein. Specifically, some embodiments of the present disclosure relate to reducing, controlling, or otherwise mitigating encroachment (e.g., physical and electrical encroachment) in layers of a magnetoresistive stack.

All numeric values disclosed herein (including all disclosed thickness values, limits, and ranges) may have a variation of ±10% (unless a different variation is specified) from the disclosed numeric value. For example, a layer disclosed as being “t” units thick can vary in thickness from (t−0.1t) to (t+0.1t) units. Further, all relative terms such as “about,” “substantially,” “approximately,” etc. are used to indicate a possible variation of ±10% (unless noted otherwise or another variation is specified).

It should be noted that the description set forth herein is merely illustrative in nature and is not intended to limit the embodiments of the subject matter, or the application and uses of such embodiments. Any implementation described herein as exemplary is not to be construed as preferred or advantageous over other implementations. Rather, the term “exemplary” is used in the sense of example or “illustrative,” rather than “ideal.” The terms “comprise,” “include,” “have,” “with,” and any variations thereof are used synonymously to denote or describe a non-exclusive inclusion. As such, a device or a method that uses such terms does not include only those elements or steps, but may include other elements and steps not expressly listed or inherent to such device and method. Further, the terms “first,” “second,” and the like, herein do not denote any order, quantity, or importance, but rather are used to distinguish one element from another. Similarly, terms of relative orientation, such as “top,” “bottom,” “left,” “right,” etc. are used with reference to the orientation of the structure(s) illustrated in the figures being described. Moreover, the terms “a” and “an” herein do not denote a limitation of quantity, but rather denote the presence of at least one of the referenced item.

In this disclosure, the term “region” is used generally to refer to one or more layers of material. That is, a region (as used herein) may include a single layer (or film or coating) of material or multiple layers or coatings (or films) of materials stacked one on top of another to form a multi-layer system. Further, although in the description below, the different regions in the disclosed stack are sometimes referred to by specific names (such as, e.g., capping layer, reference layer, free layer, fixed layer, tunnel barrier, transition layer, etc.), this is only for ease of description and not intended as a functional description of the layer.

Magnetoresistive stacks, such as magnetoresistive memory stacks within MRAM devices, are being built in increasingly small sizes, e.g., to accommodate more stacks in a given form factor, thus allowing for greater memory capacity and, for example, advanced process nodes. As magnetoresistive stacks shrink in size (e.g., along a diameter or width dimension), however, maintaining certain characteristics of the stacks may become more challenging. For example, maintaining a low, predictable switching voltage (V_{C}) of free regions within magnetoresistive stacks remains important to the usability, endurance, and quality of the magnetoresistive stacks themselves as well as devices including the magnetoresistive stacks. But as stack sizes shrink, the relative physical proportions of each stack change, which may alter behavior and electrical characteristics of layers within the stack and the stack as a whole.

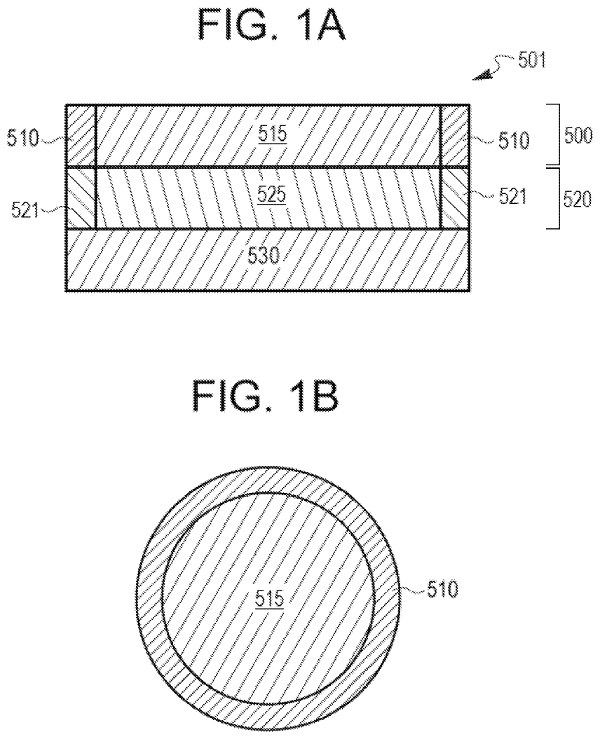

For reference, FIGS. 1A and 1B are simplified schematic depictions of an example magnetoresistive stack 501 having a free region 500, an intermediate layer (e.g., a dielectric material configured to act as a tunnel barrier) 520, and a fixed region 530 that, in some embodiments, may include a synthetic antiferromagnet (SAF). FIG. 1A shows a cross-sectional side view of stack 501, and FIG. 1B shows a top down plan view of stack 501. Free region 500 is depicted as having a peripheral portion 510 at and near the circumferential edge of free region 500, and an inner portion 515 surrounded by peripheral portion 510. Similarly, intermediate layer 520 may include a peripheral portion 521 at and near the circumferential edge of intermediate layer 520, and an inner portion 525 surrounded by peripheral portion 521. The peripheral portion of a layer or region (e.g., peripheral portions 510, 521) may be dominated by somewhat different characteristics (e.g., material and/or electrical characteristics) than the inner portion of the layer or region (e.g., inner portions 515, 525), as described further below. As the manufactured size of a magnetoresistive stack shrinks, the proportion of the volume of the peripheral portion of each layer or region of the stack (e.g., peripheral portions 510, 521) to the volume of inner portion of each layer (e.g., inner portions 515, 525) increases, such that characteristics of each layer or region as a whole become more affected by properties of the layer or region's peripheral portion. Moreover, characteristics of each layer or region may become less consistent due to differences between the layer or region's peripheral and inner portions. This may be particularly true of magnetoresistive stacks having electrical diameters of less than about 20 nm.

One cause of difference in characteristics between the peripheral and inner portions of a layer or region is encroachment. Encroachment may refer to electrical encroachment, magnetic encroachment, or both. Electrical encroachment in particular may result in an increased electrical resistance in the portions affected by encroachment. Encroachment may result from certain manufacturing processes, such as, e.g., an etching step used to pattern the magnetoresistive stacks, as described in greater detail below. In some cases, encroachment may be observed as an increase in switching voltage (V_{C}) and an increase in switching voltage distribution (V_{Cσ}) as magnetoresistive stack size decreases, caused by differences between a peripheral portion and an inner portion of a region.

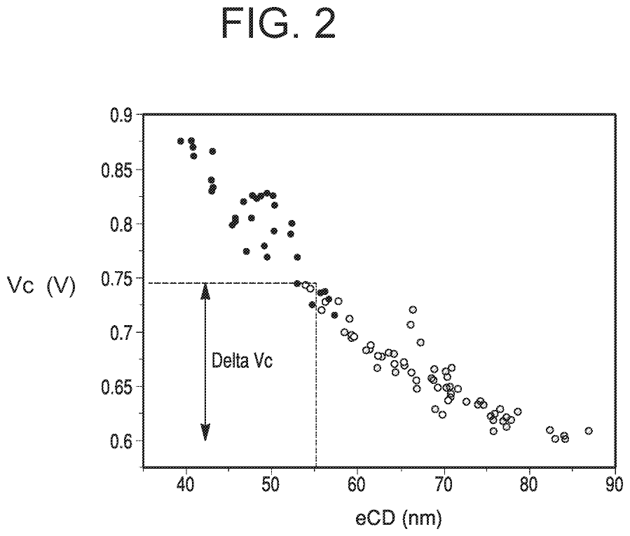

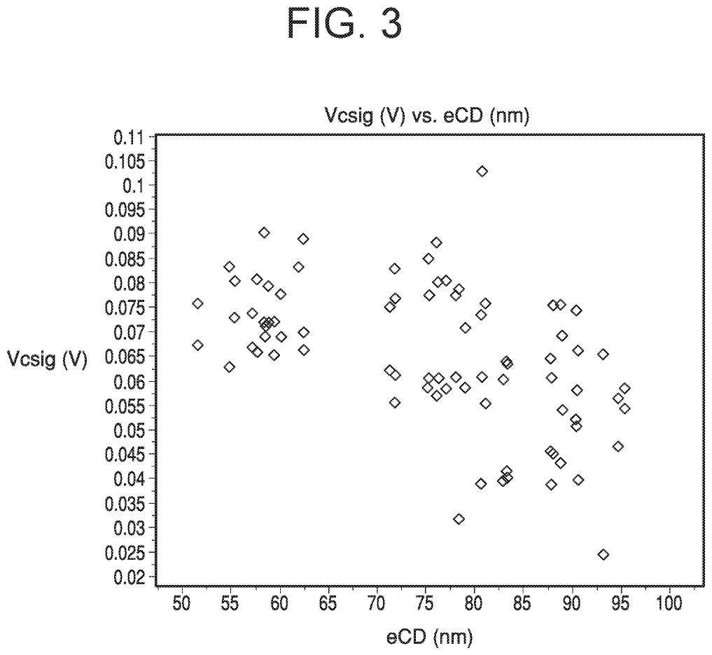

Magnetic encroachment in particular may refer to an effect of damage to the edge of layers or regions in a magnetoresistive stack, e.g., during an etch process (e.g., damage to peripheral portion 510 of free region 500 in FIG. 1A). Such damage to a free region of a magnetoresistive stack may cause a lower perpendicular anisotropy field Hk of the free region, a lower magnetic moment of the free region, a higher effective damping of the free region, and/or a change in exchange stiffness, which may result in undesirably higher switching voltages V_{C}, higher switching voltage distributions V_{Cσ}, and lower thermal stability (Eb). For example, in a free region with high encroachment, an inner portion of the free region may switch first at a lower voltage, followed by switching of the peripheral portion of the same free region at a higher voltage. The overall switching of the region therefore becomes more complex and requires higher energy input. FIG. 2 depicts a typical correlation between electrical diameter of a magnetoresistive stack (eCD) and switching voltage V_{C}. Electrical diameter of a magnetoresistive stack is calculated using the RA, or Resistance-Area product, to obtain a diameter of the stack based on the stack's resistance. As can be seen, lower electrical diameters are associated with increased V_{C} values. FIG. 3 likewise depicts a typical correlation between eCD and V_{Cσ}. Once again, V_{Cσ} tends to be higher for magnetoresistive stacks having smaller diameters. Increases in switching voltage distributions V_{Cσ} may be due to, e.g., a proportionally larger variation in magnetoresistive stack size as stack sizes decrease (due to, e.g., manufacturing or processing variability at smaller scales), or to abnormal magnetic switching.

Another type of encroachment may include electrical encroachment. Electrical encroachment may refer to oxidation of the intermediate layers (e.g., tunnel barrier layer(s)) in a magnetoresistive stack (e.g., oxidation of peripheral portion 521 in tunnel barrier layer 520, in FIG. 1A), which may cause the effective current path of spin-polarized current through the tunnel barrier layer(s) to shrink, and may lead to non-uniform switching in the free layer.

A low switching voltage Vc may be advantageous, e.g., to preserve energy consumption and to reduce wear in a magnetoresistive device. In practice, to account for switching voltage distribution V_{Cσ} across a magnetoresistive stack in a magnetoresistive memory device, a voltage determined by the calculation A×V_{Cσ} may be applied to the magnetoresistive stack or device in addition to a median switching voltage V_{C}, where A is a multiplier chosen to account for a bit error rate (BER) of the device. As noted, switching voltage distribution V_{Cσ} also may increase for a magnetoresistive stack as the size of the stack decreases. Thus, it may be advantageous to be mindful of, and to control or otherwise mitigate, rises in V_{C} and V_{Cσ}, as magnetoresistive stacks are made in smaller sizes.

One general method by which increases in V_{C} and V_{Cσ} may be controlled or reduced is to establish increased control of the perpendicular anisotropy field Hk of the free region of a magnetoresistive stack. In particular, free regions having higher Hk values may, to a certain extent, exhibit relatively smaller increases in in V_{C} and V_{Cσ} as the diameter of a free region decreases, as compared to free regions having lower Hk values.

Methods of increasing the Hk values of free regions are described in further detail below. First, however, reference will be made to general characteristics of magnetoresistive stacks and devices to which the present disclosure may apply.

In one exemplary aspect, a magnetoresistive device of the present disclosure may be a magnetic tunnel junction type device (MTJ device). The MTJ device may be implemented, for example, as an MRAM element (“memory element”), a magnetoresistive sensor, a magnetoresistive transducer, etc. An MTJ device typically includes a magnetoresistive stack/structure that includes intermediate layer(s) positioned (or sandwiched) between ferromagnetic regions. The intermediate layer(s) may be made of dielectric materials and function as tunnel barriers in some embodiments. In other embodiments, the intermediate layer(s) may be made of conductive materials (including, but not limited to, a non-magnetic conductive material such as, e.g., copper, gold, or alloys thereof) to form a giant magnetoresistive (GMR) or GMR-type device. The principles of the present disclosure may apply to the various types of magnetoresistive devices, including, e.g., GMR and TMR devices.

In one aspect, the magnetoresistive devices of the current disclosure include magnetic tunnel junction bits (MTJ bits). These MTJ bits may be formed from a magnetoresistive stack/structure that may include, or may be operably coupled to, one or more electrically conductive electrodes, vias, or conductors on either side of the magnetoresistive stack/structure. As described in further detail below, the magnetoresistive stack/structure that forms the MTJ bits may include many different regions and/or layers of material, where some of the regions and/or layers include magnetic materials, and whereas others do not. In one embodiment, the methods of manufacturing the disclosed devices may include sequentially depositing, growing, sputtering, evaporating, and/or providing (collectively referred herein as “depositing” or other verb tense (e.g., “deposit” or “deposited”)) layers and regions which, after further processing (for example, etching) form an MTJ bit (or a plurality of MTJ bits stacked one on top of another or arranged in an array).

Magnetoresistive stacks/structures that form an MTJ bit may be formed between a first electrode/via/line and a second electrode/via/line, both of which may permit electrical access to the MTJ bit by allowing for electrical connectivity to circuitry and other elements of the magnetoresistive device. Between the electrodes/vias/lines are regions of different materials. The magnetoresistive stacks/structures that form the MTJ bits may include at least one fixed magnetic region (which may include, among other things, one or more ferromagnetic layers), at least one free magnetic region (which may include, among other things, one or more ferromagnetic layers), and one or more intermediate regions or layers disposed between a fixed region and a free region. In some embodiments, the one or more intermediate regions or layers may be made of dielectric materials. However, in other embodiments, the one or more intermediate regions may be made of electrically conductive materials. In some embodiments, the electrode/via/line on one or both sides of the magnetoresistive stack/structure may be eliminated, and an interconnect (e.g., bit line) may be formed in contact with the magnetoresistive stack/structure.

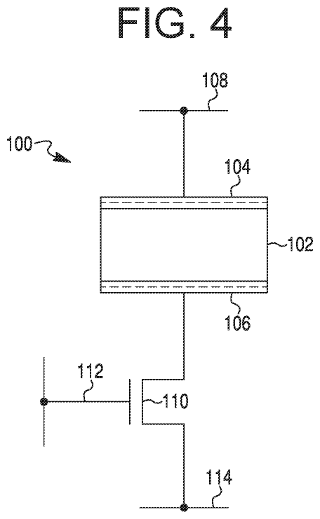

Magnetoresistive devices to which the present disclosure applies may include a sensor architecture or a memory architecture (among other architectures). For example, FIG. 4 schematically depicts a memory configuration 100 including a magnetoresistive stack 102 (which may include one or more MTJ bits). Magnetoresistive stack 102 may be configured to couple or connect to an access transistor 110 and to various conductors (e.g., source line conductor 114, word line (WL) conductor 112, bit line (BL) conductor 108), which may carry one or more control signals, via electrically conductive electrodes 104, 106. Magnetoresistive stack 102 may be used in any suitable application, including, e.g., in a memory configuration.

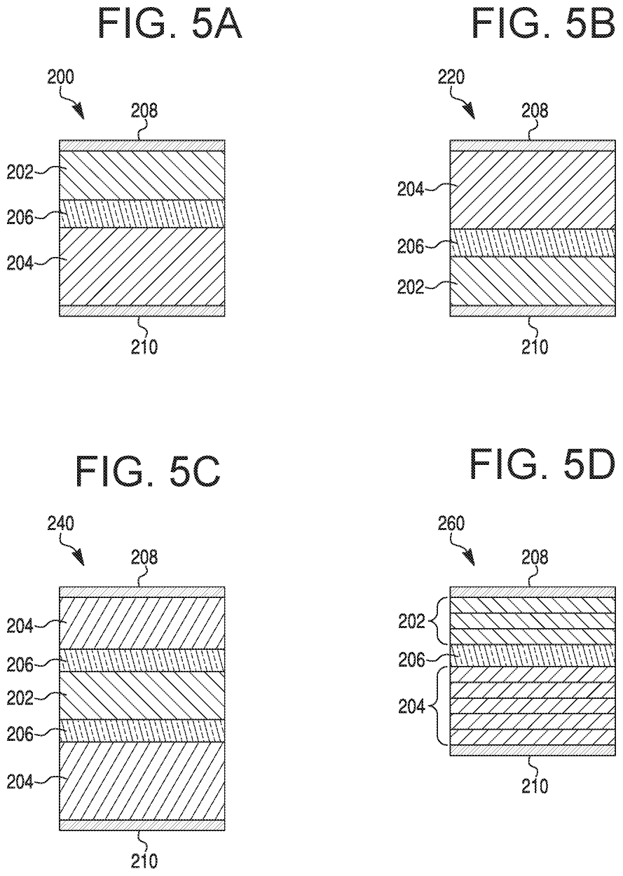

FIGS. 5A-5D depict cross sectional, schematic views of exemplary MTJ bits to which the present disclosure may apply. FIG. 5A depicts an MTJ bit 200 having a free region 202 stacked over a fixed region 204, and separated from fixed region 204 by an intermediate region 206. MTJ bit 200 also includes a top electrode 208 and a bottom electrode 210. FIG. 5B depicts a second MTJ bit 220, in which fixed region 204 is stacked above free region 202 with intermediate region 206 disposed therebetween. FIG. 5C depicts yet another MTJ bit 240, including a free region 202 sandwiched between two fixed regions 204, and separated from each of the two fixed regions 204 by an intermediate region 206. FIG. 5D depicts a further MTJ bit 260, in which multiple regions are stacked adjacent to one another to form fixed region 204, followed by an intermediate region 206 above fixed region 204, followed by multiple regions stacked adjacent to one another above intermediate region 206, to form free region 202. As mentioned, in some embodiments, one or both of electrodes 208, 210 of an MTJ bit may be eliminated and/or replaced with an interconnect configured to be in contact with the MTJ bit. Although not depicted, adjacent fixed regions and adjacent free regions may each be separated by an interlayer material, such as a dielectric material or a conductive material. In order to provide electrical coupling between multiple free regions or multiple fixed regions separated by dielectric materials, vias may be formed through the interlayer dielectric material (or ILD) that separates adjacent conductive layers.

The free regions, fixed regions, and intermediate layers or regions may be formed from any suitable materials now-known or developed in the future. Exemplary materials for free regions may include conductive materials such as, e.g., ferromagnetic alloys (comprising some or all of cobalt, iron, nickel, platinum, palladium, and boron, etc.). Further exemplary materials may include copper, tantalum, tantalum nitride, aluminum, titanium, or tungsten. Exemplary materials for fixed regions may also include any of these conductive materials, or other now-known or future-developed materials. In some embodiments, fixed regions may also include a synthetic antiferromagnetic layer, which may include, e.g., cobalt, iron, and/or a nonmagnetic material, such as ruthenium.

Intermediate regions or materials may refer to barrier layers, such as tunnel barrier layers, or to other interlayer regions that may or may not serve as barrier layers. Tunnel barrier layers may be formed from, e.g., dielectric materials. Conventional dielectric materials include any now-known or future-developed electrically insulating materials (oxide, nitride, carbonitride, etc.), such as, for example, silicon dioxide (SiO₂), TEOS (Tetraethyl Orthosilicate), silicon nitride, aluminum oxide, magnesium oxide, carbon doped oxide, organo silicate glass, spin-on organics, etc., or combinations thereof. These dielectric materials typically have a relatively high dielectric constant. As magnetoresistive and memory devices scale smaller, spacing between interconnects in the circuit decrease. The associated higher resistance and capacitive coupling may cause signal delay, known as RC delay, in the circuit. Lowering the dielectric constant, or the “k” value, of an interlayer dielectric decreases the RC delay, lowers power consumption, and reduces “cross-talk” between nearby interconnects. There are many known low-k (or ultra low-k) materials that may be used as dielectric materials in magnetoresistive devices. See, for example, “Materials chemistry for low-k materials,” Materials Today, Volume 9, Issue 3, March 2006, Pages 22-31, which is incorporated by reference in its entirety herein. There is also a significant amount of ongoing research to determine suitable low-k and ultra low-k ILD materials for IC applications. Typically, such may include any currently-known (flourine-doped silicon dioxide or silicas, carbon-doped silicon dioxide or silicas (e.g., SiCOH), porous silicon dioxide, spin-on organic polymeric dielectrics, spin-on silicon based polymeric dielectric SiCOH, etc.) or future-developed ILD material.

In other embodiments, intermediate regions or layer(s) may be made of conductive materials (including, but not limited to, a non-magnetic conductive material such as, e.g., copper, gold, or alloys thereof) to form a giant magnetoresistive (GMR) or GMR-type device.

Vias formed through the ILD material(s) may be formed from any suitable material. Without limitation, the vias may be formed by any electrically conductive material (e.g., copper (Cu), tantalum (Ta), tantalum nitride (TaN), cobalt tungsten phosphide (CoWP), copper with Ta/TaN or CoWP as a barrier material, etc.). Vias may be holes, cavities, or openings in the ILD within which electrically conductive material is deposited or otherwise provided in order to provide an electrical path or conduit between two metal layers on either side of the ILD. In some aspects, the ILD may surround and insulate the vias and/or interconnect wiring of a device in which an MTJ bit or other magnetoresistive stack is disposed.

It will be apparent to one of ordinary skill in the art that many more variations of MTJ bits and magnetoresistive stacks may be suitable for use in the present disclosure without departing from the present disclosure's scope. For example, two, three, four, or more MTJ bits may be stacked on top of one another. Moreover, magnetoresistive stacks to which the present disclosure may apply may include any number or type of diodes, interconnects, vias, or other features to render the stacks suitable for use in a variety of applications.

One or more signals may be passed through some or all of a magnetoresistive stack (e.g., between electrodes in a stack). For example, the signal may be a read signal, such as a read current. Such a signal may read or otherwise detect the magnetic state of the stack through which it passes. The magnetic state of a magnetoresistive stack according to the present disclosure may be changed using a further signal, such as a write signal (e.g., a voltage pulse). Diodes, vias, and other features may be used to selectively apply a write signal to change the magnetic state of some or all of a magnetoresistive stack.

As alluded to above, a free region and a fixed region of a magnetoresistive stack (e.g., in an MTJ bit configuration) may have two magnetic states. A first, or relatively “high resistance” or “antiparallel” magnetic state may result when the magnetization vectors of the fixed and free regions are in opposite directions. This relatively high resistance state may correspond to a digital “1” when the stack is implemented in a memory configuration or application. A second, or relatively “low resistance” or “parallel” magnetic state may result when the magnetization vectors of the fixed and free regions are in the same direction. This relatively low resistance state may correspond to a digital “0” when the stack is implemented in a memory configuration or application.

A magnetoresistive stack may have a critical signal strength or value that may be applied in order to change the magnetic state of the stack (e.g., to change the magnetic state of the stack from a parallel, low-resistance orientation, where the magnetization vectors of a free region and a fixed region are in the same direction, to an antiparallel, high-resistance orientation, where the magnetization vectors of the free and fixed regions are in opposing directions). This may be referred to as a write signal. In some embodiments, for example, the write signal may require a threshold switching voltage V_{C} to switch the magnetization vector of a free region of the magnetoresistive stack. As parts of a magnetoresistive stack (either within one region or layer of the stack, or amongst different regions or layers) may differ in their required V_{C}, the switching voltage V_{C} of a magnetoresistive stack or region may generally be a median switching voltage. The distribution of switching voltages in one or more magnetoresistive stacks may be referred to as V_{Cσ}.

Magnetoresistive stacks to which the present disclosure may apply may be manufactured according to any suitable method now known, or developed in the future. For example, layers of materials may be deposited to form regions of the magnetoresistive stacks. Since suitable integrated circuit fabrication techniques (e.g., deposition, sputtering, evaporation, plating, etc.) that may be used to form the different regions are known to those of ordinary skill in the art, they are not described here in great detail. In some embodiments, forming some of the regions may involve thin-film deposition processes, including, but not limited to, physical vapor deposition techniques such as ion beam sputtering and magnetron sputtering. Forming thin insulating layers may involve physical vapor deposition from an oxide target, such as by radio-frequency (RF) sputtering, or by deposition of a thin metallic film followed by an oxidation step, such as oxygen plasma oxidation, oxygen radical oxidation, or natural oxidation by exposure to a low-pressure oxygen environment. In some embodiments, formation of some or all of the regions of a magnetoresistive stack may also involve known processing steps such as, for example, selective deposition, photolithography processing, etching, etc., in accordance with any of the various conventional techniques known in the semiconductor industry.

In some embodiments, during deposition of the disclosed fixed and free regions, a magnetic field may be provided to set a preferred easy magnetic axis of the region (e.g., via induced anisotropy). Similarly, a strong magnetic field applied during the post-deposition high-temperature anneal step may be used to induce a preferred easy axis and a preferred pinning direction for any antiferromagnetically pinned materials. Additionally, deposition of fixed and free regions may occur in a variety of orders. For example, in some cases, a fixed or antiferromagnetic region may be formed before a free region in a bottom-pinned arrangement, and in other cases, the free region may be formed first on, e.g., a seeding layer, with the fixed region formed above the free region in a top-pinned arrangement. In particular, magnetoresistive stacks that have been created using one or more etching processes may be suitable for use with the present disclosure.

Reference will now be made to systems and methods by which Hk of a free region may be increased, such that the V_{C} and V_{Cσ} of the free region may be less affected by magnetic encroachment.

In some embodiments, Hk of a free region may be increased by engineering an interface between the free region and an adjacent nonmagnetic intermediate layer, e.g., a tunnel barrier layer. In particular, a free region adjacent to a tunnel barrier layer formed from magnesium oxide may have increased Hk if iron is used in an interfacing layer between them. For example, in some embodiments, an interfacing layer comprising magnesium oxide and iron may be used. In further embodiments, pure iron or substantially pure iron may be used. In some embodiments, boron may be used, either alone or in combination with iron. For example, an interfacing layer may include anywhere between about 0% boron and 100% iron, and about 100% boron and 0% iron. In some embodiments, for example, an interfacing layer may include between about 1% boron and about 50% boron, between about 50% boron and about 99% boron, between about 5% boron and about 40% boron, between about 60% boron and about 95% boron, between about 10% boron and about 30% boron, between about 70% boron and about 90% boron, between about 15% boron and about 25% boron, between about 75% boron and about 85% boron, or between about 40% boron and about 60% boron, with the remainder of the layer comprising iron. For example, in some embodiments, an interfacing layer may include about 10% boron, about 20% boron, about 30% boron, about 40% boron, about 50% boron, about 60% boron, about 70% boron, about 80% boron, or about 90% boron, with the remainder of the layer comprising iron. A suitable interfacing layer may have a thickness of, e.g., between about 0.3 and about 6 angstroms, such as between about 0.5 and about 5 angstroms, between about 1 and about 4 angstroms, or between about 2 and about 3 angstroms.

In some embodiments, Hk of a free region may additionally or alternatively be increased by modifying the materials used for the free region. Free regions may be constructed from alloys such as, e.g., a cobalt iron boron alloy, iron boron alloy, or cobalt iron alloy. This may be exchanged or supplemented with other alloys. Additional suitable alloys may include, e.g., cobalt platinum, cobalt nickel, cobalt palladium. In some embodiments, a free region including multiple layers may include multiple layers of a cobalt platinum alloy, multiple layers of a cobalt nickel alloy, multiple layers of a cobalt palladium alloy, or a combination of layers made of two or more such alloys. In some embodiments, suitable alloys for use in increasing Hk of a free region may include an alloy including iron and boron, e.g., an iron boron alloy. In further embodiments, a cobalt-iron-boron alloy in a free region may be replaced with an alloy having a higher boron content, to increase the Hk of the free region.

In some embodiments, Hk may additionally or alternatively be increased by modifying interlayer materials in or adjacent to the free region. Suitable interlayer materials may include, for example, molybdenum, tungsten, tantalum, chromium, vanadium, or any non-magnetic transition metal.

In some embodiments, Hk of a top-pinned magnetoresistive stack, or a magnetoresistive stack in which the fixed region is above the free region, may be higher than Hk of a bottom-pinned magnetoresistive stack, or a magnetoresistive stack in which the fixed region is below the free region. In a magnetoresistive stack that is constructed by first layering the free region on a seeding layer, followed by an interlayer material on the free region, followed by a fixed region on the interlayer material, improved seeding of the free region may be possible as compared to a magnetoresistive stack that is constructed by layering a fixed region on a substrate, followed by an interlayer material, and a free region on top.

In some embodiments, Hk of a free region in a magnetoresistive stack may additionally or alternatively be increased by annealing the stack at a temperature of less than about 400° C. Annealing is a known step in the manufacture of magnetoresistive stacks and magnetic memory devices. However, annealing some stack materials at temperatures of about 400° C. is correlated with decreases in Hk. Lower annealing temperatures may mitigate these decreases in the case of these stack material combinations. For example, layers of a magnetoresistive stack may be deposited and then annealed at between about 200° C. and about 380° C., between about 220° C. and about 380° C., between about 250° C. and about 350° C., between about 275° C. and about 325° C., between about 300° C. and about 350° C., or between about 325° C. and about 375° C. For example, a suitable annealing temperature may be about 240° C., about 250° C., about 275° C., about 300° C., about 325° C., about 350° C., about 375° C., or about 385° C. In some stack material combinations, Hk may increase with an increase in annealing temperature. In particular, in some embedded applications, annealing stack materials at 400° C. or higher from between about 30 minutes and about 3 hours (e.g., between about 30 minutes and about 2 hours) may assist in tuning the Hk at high temperatures.

Raising Hk of a free region generally may also be accomplished by reducing the magnetic moment of the free region. For example, increasing a relative content of a metal having lower magnetic moment (e.g., boron) in a free region may decrease the magnetic moment of the free region. The extent to which magnetic moment of a free region may affect Hk may depend on the materials in the free region. For example, a change of 10 μemu/cm² (micro electromagnetic units per centimeter squared) may lead to a 1000 Oe change in Hk, depending on what material within the free layer is being changed. As another example, decreasing the mass of a free region may reduce the magnetic moment of the free region, thereby increasing the Hk of the free region.

The above-described alterations, methods, and systems may be each performed alone or in combination with one or more methods and systems in order to raise the Hk of a free region in a magnetoresistive stack. Further, the described methods may be incorporated into a process of fabricating a magnetoresistive (e.g., MTJ) device in any suitable manner. Since the additional steps needed to form an MTJ device are known to those of ordinary skill in the art, they are not described herein. Additionally, the described method(s) may be incorporated into a more comprehensive procedure or process having additional functionality not described herein. Moreover, the above-described alterations, methods, and systems are exemplary, and many modifications are possible. For example, some of the above-described methods may be modified, eliminated, or otherwise combined with other steps, whether described or not described herein. It should also be noted that, although not recited here, the described method(s) may include a number of additional or alternative steps.

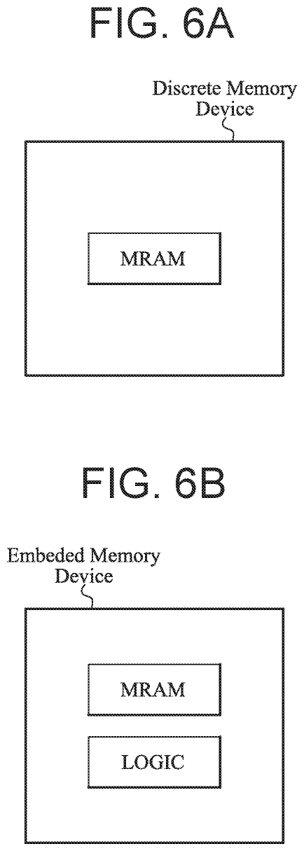

Devices and methods of the current disclosure may be applicable to forming an integrated circuit comprising a discrete memory device (e.g., as shown in FIG. 6A) or an embedded memory device having a logic therein (e.g., as shown in FIG. 6B), each including MRAM, which, in one embodiment is representative of one or more arrays of MRAM having a plurality of magnetoresistive stacks, according to certain aspects of certain embodiments disclosed herein.

Advantageously, systems and methods described herein may provide control of V_{C} and V_{Cσ} by modifying the magnetic properties of the free layer in a magnetoresistive stack, optionally allowing for control of V_{C} and V_{Cσ} without altering etch processes. This may assist in more manufacturable and useable magnetoresistive products, by keeping the total required voltage applied to a sufficiently low level. Additionally, practical limitations of circumventing process-related damages to the free region in order to keep V_{C} and V_{Cσ} at manageable levels may be overcome. Such alterations to the free layer may provide an extra controllable variable to adjust the dependency of V_{C} and V_{Cσ} on magnetoresistive stack size (e.g., stack diameter). Increasing Hk of a magnetoresistive stack's free layer may make the peripheral region of the free layer less susceptible to magnetic damage that might otherwise further alter the switching characteristics of the free layer and the stack as a whole. In practice, however, high Hk may result in high V_{C}, as V_{C} varies with total magnetic moment of the free layer (MS*t) and Hk as follows:

Vc˜Ms*t*Hk

Thus, systems and methods described herein may be applied to reach a preferred balance between the needs for low V_{C} and low V_{Cσ}. In some embodiments, it may be preferable to lower both Vc and V_{Cσ} as much as possible. In practice, in addition to lowering V_{Cσ}, it may be beneficial to lower Vc to V_{Cσ} multiplied by a coefficient representing an error rate in the system.

Aspects of the present disclosure relate to magnetoresistive devices. In some embodiments, a magnetoresistive device may include a first ferromagnetic region, a second ferromagnetic region, an intermediate region formed of a dielectric material positioned between the first ferromagnetic region and the second ferromagnetic region, wherein the device includes a component configured to increase perpendicular anisotropy of the first ferromagnetic region. In some embodiments, the component may include a ferromagnetic layer in the first ferromagnetic region, the ferromagnetic layer including a platinum or palladium alloy. In some embodiments, the component may include an interfacing layer in between the first ferromagnetic region and the intermediate region, wherein the interfacing layer includes boron. For example, the interfacing layer may be comprised of at least 50% boron, or at least 80% boron. In some embodiments, the interfacing layer may have a thickness of about 0.5 Angstroms to about 5 Angstroms.

In some embodiments, the component may include a ferromagnetic layer in the first ferromagnetic region, the ferromagnetic layer including boron. In some embodiments, the component may include a plurality of ferromagnetic layers in the first ferromagnetic region, wherein at least one of the plurality of ferromagnetic layers may include boron and at least one of the plurality of ferromagnetic layers may include a cobalt-platinum alloy or a cobalt-palladium alloy. In some embodiments, the component may include an interlayer between two ferromagnetic layers in the first ferromagnetic region, wherein the interlayer includes one of molybdenum or tungsten. In some embodiments, the component may include an interlayer between two ferromagnetic layers in the first ferromagnetic region, wherein the interlayer may include a non-magnetic transition metal.

In further embodiments, a magnetoresistive device may include a first ferromagnetic region having a plurality of layers and at least one interlayer between adjacent layers of the plurality of layers, wherein at least two layers of the plurality of layers include a cobalt-platinum alloy, a second ferromagnetic region, and an intermediate region positioned between the first ferromagnetic region and the second ferromagnetic region. In some embodiments, the at least one interlayer may include a non-magnetic transition metal. In some embodiments, the first ferromagnetic region, the second ferromagnetic region, and the intermediate region may form a magnetoresistive stack, wherein the magnetoresistive stack is top-pinned.

In further embodiments, a method for increasing perpendicular anisotropy in a ferromagnetic region of a magnetoresistive device may include depositing a first material on a seeding layer to form a first ferromagnetic region having a switchable magnetization vector, and after depositing the first material, depositing a second material to form a second ferromagnetic region having a fixed magnetization vector, wherein the second material is separated from the first ferromagnetic region by a dielectric material and forms a magnetoresistive stack with the first ferromagnetic region and the dielectric material. In some embodiments, the method may include annealing the magnetoresistive stack at a temperature of about 385° C. or less or about 300° C. or less. In some embodiments, the first material may include a cobalt-platinum alloy or a cobalt-palladium alloy.

In some embodiments, the method may further include, after depositing the first material and before depositing the second material, depositing an interfacing material on the first material, wherein the interfacing material comprises boron, and after depositing the interfacing material, depositing the dielectric material on the interfacing material. In some embodiments, the interfacing material may comprise at least 50% boron. In some embodiments, the interfacing material may be deposited to form an interfacing layer having a thickness of about 0.5 angstroms to about 5 angstroms.

Although various embodiments of the present disclosure have been illustrated and described herein, it will be readily apparent to those skilled in the art that various modifications may be made without departing from the present disclosure.

What is claimed is:

1. A magnetoresistive device, comprising:
a first ferromagnetic region;
a second ferromagnetic region; and
an intermediate region formed of a dielectric material positioned between the first ferromagnetic region and the second ferromagnetic region,
wherein the device includes a component configured to increase perpendicular anisotropy of the first ferromagnetic region.

2. The magnetoresistive device of claim 1, wherein the component includes a ferromagnetic layer in the first ferromagnetic region, the ferromagnetic layer including a platinum or palladium alloy.

3. The magnetoresistive device of claim 1, wherein the component includes an interfacing layer in between the first ferromagnetic region and the intermediate region, and wherein the interfacing layer includes boron.

4. The magnetoresistive device of claim 3, wherein the interfacing layer is comprised of at least 50% boron.

5. The magnetoresistive device of claim 3, wherein the interfacing layer is comprised of at least 80% boron.

6. The magnetoresistive device of claim 3, wherein the interfacing layer has a thickness of about 0.5 Angstroms to about 5 Angstroms.

7. The magnetoresistive device of claim 1, wherein the component includes a ferromagnetic layer in the first ferromagnetic region, the ferromagnetic layer including boron.

8. The magnetoresistive device of claim 1, wherein the component includes a plurality of ferromagnetic layers in the first ferromagnetic region, wherein at least one of the plurality of ferromagnetic layers includes boron and at least one of the plurality of ferromagnetic layers includes a cobalt-platinum alloy or a cobalt-palladium alloy.

9. The magnetoresistive device of claim 1, wherein the component includes an interlayer between two ferromagnetic layers in the first ferromagnetic region, and wherein the interlayer includes one of molybdenum or tungsten.

10. The magnetoresistive device of claim 1, wherein the component includes an interlayer between two ferromagnetic layers in the first ferromagnetic region, and wherein the interlayer includes a non-magnetic transition metal.

11. A magnetoresistive device, comprising:
a first ferromagnetic region having a plurality of layers and at least one interlayer between adjacent layers of the plurality of layers, wherein at least two layers of the plurality of layers include a cobalt-platinum alloy;
a second ferromagnetic region; and
an intermediate region positioned between the first ferromagnetic region and the second ferromagnetic region.

12. The device of claim 11, wherein the at least one interlayer includes a non-magnetic transition metal.

13. The device of claim 11, wherein the first ferromagnetic region, the second ferromagnetic region, and the intermediate region form a magnetoresistive stack, and wherein the magnetoresistive stack is top-pinned.

14. A method for increasing perpendicular anisotropy in a ferromagnetic region of a magnetoresistive device, comprising:
depositing a first material on a seeding layer to form a first ferromagnetic region having a switchable magnetization vector; and
after depositing the first material, depositing a second material to form a second ferromagnetic region having a fixed magnetization vector, wherein the second material is separated from the first ferromagnetic region by a dielectric material and forms a magnetoresistive stack with the first ferromagnetic region and the dielectric material.

15. The method of claim 14, further comprising annealing the magnetoresistive stack at a temperature of about 385° C. or less.

16. The method of claim 15, comprising annealing the magnetoresistive stack at a temperature of about 300° C. or less.

17. The method of claim 14, wherein the first material comprises a cobalt-platinum alloy or a cobalt-palladium alloy.

18. The method of claim 14, further comprising:
after depositing the first material and before depositing the second material, depositing an interfacing material on the first material, wherein the interfacing material comprises boron; and
after depositing the interfacing material, depositing the dielectric material on the interfacing material.

19. The method of claim 18, wherein the interfacing material comprises at least 50% boron.

20. The method of claim 18, wherein the interfacing material is deposited to form an interfacing layer having a thickness of about 0.5 angstroms to about 5 angstroms.
